(19) United States
(12) Patent Application Publication
(10) Pub. No.: US 2024/0219616 A1
(43) Pub. Date: Jul. 4, 2024

(54) DISPLAY DEVICE

(71) Applicant: SAMSUNG DISPLAY CO., LTD., Yongin-Si (KR)

(72) Inventors: Eunje JANG, Yongin-si (KR); Seonju KIM, Yongin-si (KR); Haechan PARK, Yongin-si (KR)

(21) Appl. No.: 18/497,288

(22) Filed: Oct. 30, 2023

(30) Foreign Application Priority Data
Dec. 27, 2022 (KR) 10-2022-0186429

(51) Int. Cl. G02B 5/22; G02B 5/02

(52) U.S. Cl. CPC G02B 5/223; G02B 5/0294

(57) ABSTRACT

Provided is a display device including a display panel having a pixel-defining film in which a first light-emitting opening, a second light-emitting opening, and a third light-emitting opening are defined, and a first light-emitting element, a second light-emitting element, and a third light-emitting element which are disposed respectively in the first to third light-emitting openings, and provide light of different colors, and an anti-reflection layer disposed on the display panel, and having a first color filter and a second color filter. The first color filter may overlap the first light-emitting element, and the second color filter may overlap the second light-emitting element and the third light-emitting element.

### CROSS-REFERENCE TO RELATED APPLICATIONS

This U.S. non-provisional patent application claims priority under 35 U.S.C. § 119 of Korean Patent Application No. 10-2022-0186429, filed on Dec. 27, 2022, the entire contents of which are hereby incorporated by reference.

### BACKGROUND

The present disclosure herein relates to a display device including a plurality of color filters.

A display device provides information to a user by displaying various images on a display screen. In general, a display device displays information within an assigned screen. A display device may include a display panel, an anti-reflection layer, and a window.

### SUMMARY

The present disclosure provides a display device with improved process efficiency.

An embodiment of the present disclosure provides a display device including a display panel having a pixel-defining film in which a first light-emitting opening, a second light-emitting opening, and a third light-emitting opening are defined, and a first light-emitting element, a second light-emitting element, and a third light-emitting element which are disposed respectively in the first to third light-emitting openings, and which provide light of different colors, and an anti-reflection layer disposed on the display panel, and including a first color filter and a second color filter, wherein the first color filter overlaps the first light-emitting element, and the second color filter overlaps the second light-emitting element and the third light-emitting element.

In an embodiment, the first color filter may transmit a first color, and the second color filter may transmit a second color and a third color which are different from the first color. In an embodiment, the second color filter may include a blue pigment.

In an embodiment, the second color filter may further include a green pigment.

In an embodiment, the second color filter may further include at least one of a blue-violet pigment and a yellow pigment.

In an embodiment, the anti-reflection layer may further include an overcoat layer covering the first color filter and the second color filter.

In an embodiment, the second color filter may include a first sub-color filter overlapping the second light-emitting element, and a second sub-color filter overlapping the third light-emitting element.

In an embodiment, the first sub-color filter and the second sub-color filter may be spaced apart from each other.

In an embodiment, the first sub-color filter and the second sub-color filter may include a same material.

In an embodiment, the anti-reflection layer may further include a light-blocking pattern overlapping the pixel-defining film.

In an embodiment, the first sub-color filter may have a first thickness, and the second sub-color filter may have a second thickness greater than the first thickness.

In an embodiment, the first color filter may overlap the first light-emitting element and the pixel-defining film, and the second color filter may overlap the second light-emitting element, the third light-emitting element, and the pixel-defining film.

In an embodiment, a portion of the first color filter may overlap a portion of the second color filter in a region where the pixel-defining film is disposed.

In an embodiment of the present disclosure, a display device includes a display panel having a pixel-defining film in which a first light-emitting opening, a second light-emitting opening, and a third light-emitting opening are defined, and a first light-emitting element, a second light-emitting element, and a third light-emitting element which are disposed respectively in the first to third light-emitting openings, and which provide light of different colors, and an anti-reflection layer disposed on the display panel. The anti-reflection layer may include a first color filter which transmits a first color, and a second color filter including a blue pigment and configured to transmit a second color different from the first color, and a third color different from the first color and the second color.

In an embodiment, the first color filter may overlap the first light-emitting element, and the second color filter may overlap the second light-emitting element and the third light-emitting element.

In an embodiment, the second color filter may include a first sub-color filter overlapping the second light-emitting element, and a second sub-color filter overlapping the third light-emitting element, and the first sub-color filter and the second sub-color filter may include a same material.

In an embodiment, the anti-reflection layer further may include a light-blocking pattern overlapping the pixel-defining film, and the first sub-color filter and the second sub-color filter may be spaced apart from each other.

In an embodiment, the first sub-color filter may have a first thickness, and the second sub-color filter may have a second thickness greater than the first thickness.

In an embodiment, the first color filter may overlap the first light-emitting element and the pixel-defining film, and the second color filter may overlap the second light-emitting element, the third light-emitting element, and the pixel-defining film.

In an embodiment, a portion of the first color filter may overlap a portion of the second color filter in a region where the pixel-defining film is disposed.

### BRIEF DESCRIPTION OF THE FIGURES

The accompanying drawings are included to provide a further understanding of the present disclosure, and are incorporated in and constitute a part of this specification. The drawings illustrate embodiments of the present disclosure and, together with the description, serve to explain principles of the present disclosure. In the drawings:

FIG. 1 is a perspective view of a display device according to an embodiment of the present disclosure;

FIG. 2A is a cross-sectional view schematically illustrating a display device according to an embodiment of the present disclosure;

FIG. 2B is a cross-sectional view of a display panel according to an embodiment of the present disclosure;

FIG. 3 is a cross-sectional view of a display device according to an embodiment of the present disclosure;

FIG. 4 is a cross-sectional view of a display device according to an embodiment of the present disclosure;

FIG. 5 is a cross-sectional view of a display device according to an embodiment of the present disclosure;

FIG. 6 is a cross-sectional view of a display device according to a comparative example of the present disclosure;

FIG. 7 is a cross-sectional view of a display device according to a comparative example of the present disclosure; and

FIG. 8 is a graph showing the transmittance of a second color filter in FIG. 3 versus a wavelength, and showing the respective transmittances of a red color filter, a green color filter, and a blue color filter in FIG. 7 versus a wavelength.

### DETAILED DESCRIPTION

In this specification, it will be understood that when an element (or a region, a layer, a portion, or the like) is referred to as being “on”, “connected to” or “coupled to” another element, it may be directly disposed on, connected or coupled to the other element, or intervening elements may be disposed therebetween.

Like reference numerals or symbols refer to like elements throughout. In the drawings, the thickness, the ratio, and the size of the element are exaggerated for effective description of the technical contents. As used herein, the term “and/or” includes any and all combinations of one or more of the associated listed items.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the scope of the present disclosure. Similarly, a second element, component, region, layer or section may be termed a first element, component, region, layer or section. As used herein, the singular forms, “a”, “an” and “the” are intended to include the plural forms as well, unless the context clearly indicates otherwise.

Also, terms of “below”, “on lower side”, “above”, “on upper side”, or the like may be used to describe the relationships of the elements illustrated in the drawings. These terms have relative concepts and are described on the basis of the directions indicated in the drawings.

It will be further understood that the terms “includes” and/or “have”, when used in this specification, specify the presence of stated features, integers, steps, operations, elements, components, and/or groups thereof, but do not preclude the presence or addition of one or more other features, integers, steps, operations, elements, components, and/or groups thereof.

The term “part” or “unit” refers to a software or hardware component that performs a particular function. The hardware component may include, for example, a field-programmable gate array (FPGA) or an application-specific integrated circuit (ASTIC). The software component may refer to an executable code and/or data used by an executable code in an addressable storage medium. Therefore, the software components may be, for example, object-oriented software components, class components, and task components, and may include processes, functions, properties, procedures, sub-routines, program code segments, drivers, firmware, micro-codes, circuits, data, database, data structures, tables, arrays, or variables.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, embodiments of the present disclosure will be described with reference to the accompanying drawings.

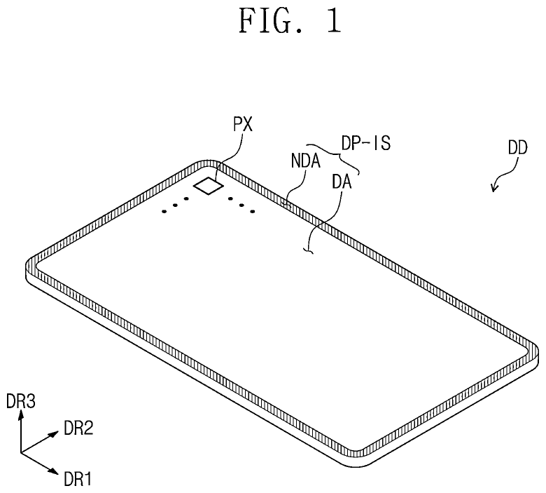

FIG. 1 is a perspective view of a display device DD according to an embodiment of the present disclosure.

In an embodiment, the display device DD may be a large electronic device such as a television, a monitor, and a billboard. The display device DD may be a small-or medium-size electronic device such as a personal computer, a laptop computer, a personal digital assistance, a car navigation unit, a game console, a smartphone, a tablet computer, and a camera. However, this is an example, and the display device DD may be employed also as other display devices without departing from the idea of the present disclosure.

Referring to FIG. 1, the display device DD may display an image on a display surface DP-IS parallel to each of a first direction DR1 and a second direction DR2 toward a third direction DR3. The image may include a still image as well as a dynamic image. The display surface DP-IS on which the image is displayed may correspond to a front surface of the display device DD.

In this embodiment, a front surface (or upper surface) and a rear surface (or lower surface) of each member are defined based on a direction in which the image is displayed. The front surface and the rear surface may be opposite to each other in a third direction DR3, and the normal direction of each of the front surface and the rear surface may be parallel to the third direction DR3. Meanwhile, the direction indicated by the first to third directions DR1, DR2, and DR3 are relative concepts, and may thus be changed to other directions. In this specification, the term “on a plane” may refer to “when being viewed in the third direction DR3”.

The display device DD may include a display region DA and a non-display region NDA. Pixels PX are disposed in the display region DA, and are not disposed in the non-display region NDA. The non-display region NDA is defined along the edge of the display surface DP-IS. The non-display region NDA may surround the display region DA. However, this is an example, and an embodiment of the present disclosure is not limited thereto. For example, according to an embodiment of the present disclosure, the non-display region NDA may be omitted, or disposed only on one side of the display region DA. FIG. 1 illustrates a flat display device DD as an example, but the display device DD may have a curved shape.

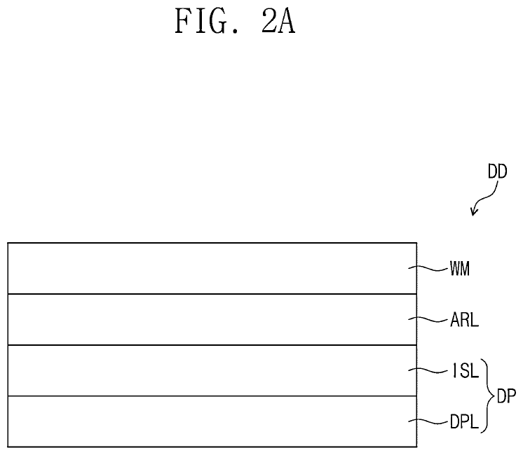

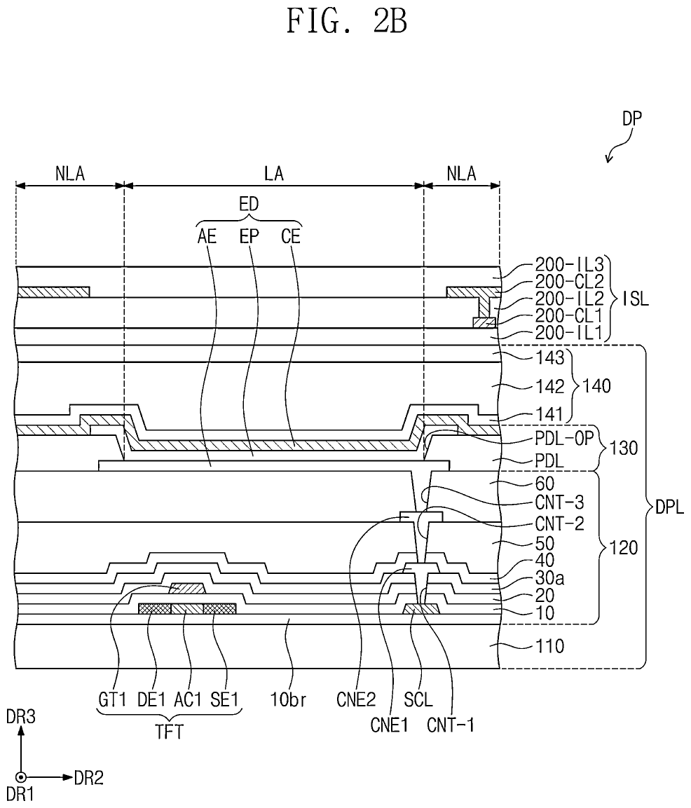

FIG. 2A is a cross-sectional view schematically illustrating a display device DD according to an embodiment of the present disclosure.

Referring to FIG. 2A, the display device DD may include a display panel DP, an anti-reflection layer ARL, and a window WM. The display panel DP may include a display layer DPL, and an input sensor layer ISL.

The display layer DPL may be an emission-type display layer. For example, the display layer DPL may be an organic light-emitting display layer, an inorganic light-emitting display layer, an organic-inorganic light-emitting display layer, a micro-LED display layer, or a nano-LED display layer.

The input sensor layer ISL may be disposed on the display layer DPL. The input sensor layer ISL may detect an external input applied from the outside. The external input may be a user's input. The user's input may include various types of external inputs such as a part of a user body, light, heat, a pen, and pressure.

The input sensor layer ISL may be formed on the display layer DPL through a continuous process. The input sensor layer ISL may be directly disposed on the display layer DPL. In this specification, when “component B is directly disposed on component A”, it may be referred to as being no intervening component present therebetween. For example, there may be no adhesive layer disposed between the input sensor layer ISL and the display layer DPL.

The anti-reflection layer ARL may be disposed on the input sensor layer ISL. The anti-reflection layer ARL may reduce the reflectance of external light. The anti-reflection layer

ARL may be directly disposed on the input sensor layer ISL through a continuous process. In some embodiments, the anti-reflection layer ARL may contact the input sensor layer ISL. The term “contact,” as used herein, refers to a direct connection (i.e., physical touching) unless the context indicates otherwise.

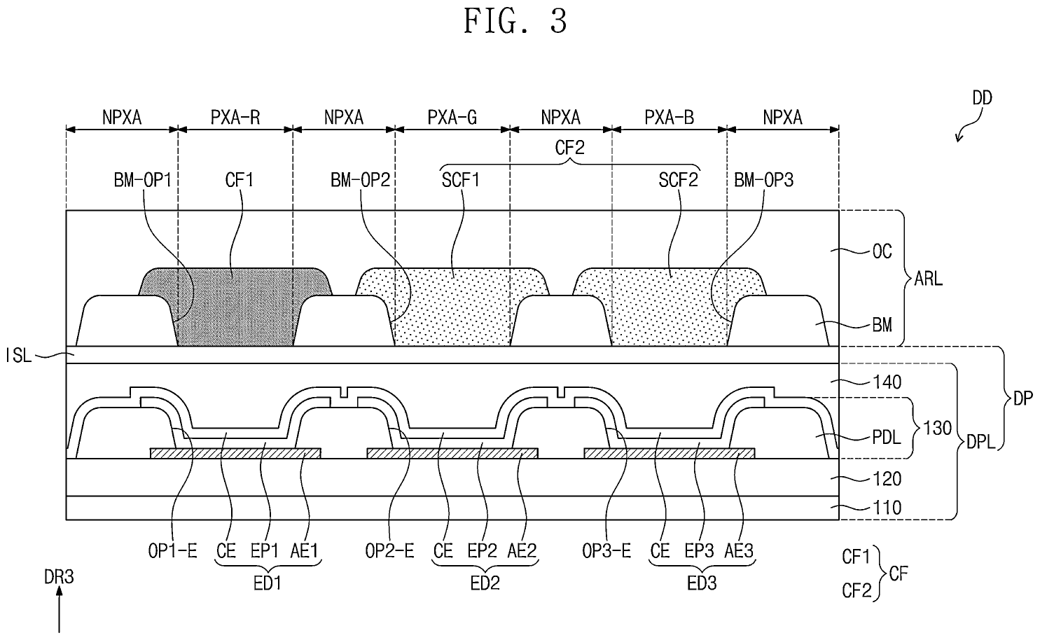

The anti-reflection layer ARL may include a color filter CF (see FIG. 3) overlapping a light-emitting region to be described later. The color filter CF may include a plurality of color filters. According to an embodiment of the present disclosure, the anti-reflection layer ARL may further include a light-blocking pattern BM (see FIG. 3). The light-blocking pattern BM may overlap a non-light-emitting region NLA of the display layer DPL. Alternatively, the light-blocking pattern BM may overlap a reflective structure (for example, a second conductive layer 200-CL2) disposed under the anti-reflection layer ARL. The anti-reflection layer ARL will be described in detail later.

The window WM may be disposed on the anti-reflection layer ARL. The window WM and the anti-reflection layer ARL may be bonded with each other by an adhesive layer. The adhesive layer may be a pressure sensitive adhesive film (PSA) or an optically clear adhesive (OCA).

The window WM may include or may be formed of at least one base layer. The base layer may be a glass substrate or a synthetic resin film. The window WM may have a multi-layer structure. The window WM may include or may be formed of a thin-film glass substrate and a synthetic resin film disposed on the thin-film glass substrate. The thin-film glass substrate and the synthetic resin film may be bonded with each other by an adhesive layer, and the adhesive layer and the synthetic resin film may be detached from the thin-film glass substrate for the replacement thereof.

According to an embodiment of the present disclosure, the adhesive layer may be omitted, and the window WM may be directly disposed on the anti-reflection layer ARL. An organic material, an inorganic material, or a ceramic material may be applied on the anti-reflection layer ARL. In some embodiments, the window WM may contact the anti-reflection layer ARL.

FIG. 2B is a cross-sectional view of a display panel DP according to an embodiment of the present disclosure.

FIG. 2B illustrates a cross-section corresponding to one light-emitting region LA and a non-light-emitting region NLA therearound. FIG. 2B exemplarily illustrates one light-emitting region LA, but the light-emitting region LA may be provided in plurality. FIG. 2B illustrates a light-emitting element ED and a transistor TFT connected thereto. The transistor may be one of a plurality of transistors included in a driving circuit of a pixel. In this embodiment, the transistor TFT may be described as a silicon transistor, but may also be a metal oxide transistor.

Referring to FIG. 2B, the display panel DP may include a display layer DPL and an input sensor layer ISL. The display layer DPL may include a base layer 110, a circuit layer 120, a light-emitting element layer 130, and a thin-film encapsulation layer 140.

The base layer 110 may provide a base surface on which the circuit layer 120 is disposed. The base layer 110 may be a rigid substrate, or a flexible substrate that is bendable, foldable, and rollable. The base layer 110 may be a glass substrate, a metal substrate, or a polymer substrate. However, an embodiment of the present disclosure is not limited thereto, and the base layer 110 may include an inorganic layer, an organic layer, or a composite material layer.

The base layer 110 may have a multi-layer structure. For example, the base layer 110 may include or may be formed of a first synthetic resin layer, a multi-layer or single-layer inorganic layer, and a second synthetic resin layer disposed on the multi-layer or single- layer inorganic layer. The first and second synthetic resin layers may each include a polyimide-based resin, but an embodiment of the present disclosure is not limited particularly thereto.

The circuit layer 120 may be disposed on the base layer 110. The circuit layer 120 may include an insulation layer, a semiconductor pattern, a conductive pattern, a signal line, a driving circuit of a pixel, and the like. For example, the circuit layer 120 may include a buffer layer 10br, first to fifth insulation layers 10, 20, 30, 40, and 50, a signal transmission region SCL, and a plurality of connection electrodes CNE1 and CNE2.

The buffer layer 10br may be disposed on the base layer 110. The buffer layer 10br may prevent diffusion of metal atoms or impurities from the base layer 110 to the semiconductor pattern thereabove. The semiconductor pattern includes an active region AC1 of the transistor TFT. A back metal layer may be additionally disposed between the base layer 110 and the buffer layer 10br. The back metal layer may be disposed under the transistor TFT, and prevent external light from reaching the transistor TFT.

The semiconductor pattern may be disposed on the buffer layer 10br. The semiconductor pattern may include a silicon semiconductor. For example, the silicon semiconductor may include amorphous silicon, polycrystalline silicon, and the like. For example, the semiconductor pattern may include a low-temperature polysilicon.

The semiconductor pattern may include a first region with high conductivity and a second region with low conductivity. The first region may be doped with an N-type dopant or a P-type dopant. A P-type transistor may include a doped region which is doped with a P-type dopant, and an N-type transistor may include a doped region which is doped with an N-type dopant. The second region may be an undoped region or a doped region which is doped with lower concentrations than the first region.

The conductivity of the first region may be greater than the conductivity of the second region, and the first region may substantially serve as an electrode or a signal line. The second region may substantially correspond to an active region (or channel) of the transistor. In other words, a portion of the semiconductor pattern may be an active region of the transistor, another portion may be a source or a drain of the transistor, and still another portion may be a connection electrode or a connection signal line.

The transistor TFT may include a source region SE1 (or source), an active region AC1 (or channel), a drain region DE1 (or drain), and a gate GT1. The source region SE1, the active region AC1, and the drain region DE1 of the transistor TFT may be formed from the semiconductor pattern. The source region SE1 and the drain region DE1 may extend from the active region AC1 in the directions opposite to each other on a cross-section. FIG. 2B illustrates a portion of the signal transmission region SCL formed from the semiconductor pattern. Although not particularly illustrated in the drawing, the signal transmission region SCL may be connected to the drain DE1 of the transistor TFT on a plane.

The first insulation layer 10 may be disposed on the buffer layer 10br. The first insulation layer 10 may cover the source SE1, the active AC1, and the drain DE1 of the transistor TFT, and the signal transmission region SCL, which are disposed on the buffer layer 10br.

The first insulation layer 10 may include or may be formed of an inorganic layer and/or organic layer, and may have a single-layer or multi-layer structure. The inorganic layer may include or may be formed of at least one of aluminum oxide, titanium oxide, silicon oxide, silicon nitride, silicon oxynitride, zirconium oxide, and hafnium oxide. In this embodiment, the first insulation layer 10 may be a silicon oxide layer as a single layer. An insulation layer of the circuit layer 120 to be described later, as well as the first insulation layer 10, may be an inorganic layer and/or organic layer, and may have a single-layer or multi-layer structure. The inorganic layer may include or may be formed of at least one of the aforementioned materials, but an embodiment of the present disclosure is not limited thereto.

The gate GT1 of the transistor TFT may be disposed on the first insulation layer 10. The gate GT1 may be a portion of a metal pattern. The gate GT1 may overlap the active region AC1. In a doping process of the semiconductor pattern, the gate GT1 may function as a mask. The gate GT1 may include or may be formed of titanium (Ti), silver (Ag), silver-containing alloy, molybdenum (Mo), molybdenum-containing alloy, aluminum (Al), aluminum-containing alloy, aluminum nitride (AlN), tungsten (W), tungsten nitride (WN), copper (Cu), indium tin oxide (ITO), or indium zinc oxide (IZO), but an embodiment of the present disclosure is not limited particularly thereto.

The second insulation layer 20 may be disposed on the first insulation layer 10, and cover the gate GT1. The third insulation layer 30 may be disposed on the second insulation layer 20. Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

The first connection electrode CNE1 may be disposed on the third insulation layer 30. The first connection electrode CNE1 may be connected to the signal transmission region SCL through a contact hole CNT-1 passing through the first to third insulation layers 10, 20, and 30. The fourth insulation layer 40 may be disposed on the third insulation layer 30 to cover the first connection electrode CNE1. The fourth insulation layer 40 may be an organic layer.

The fifth insulation layer 50 may be disposed on the fourth insulation layer 40. The second connection electrode CNE2 may be disposed on the fifth insulation layer 50. The second connection electrode CNE2 may be connected to the first connection electrode CNE1 through a contact hole CNT-2 passing through the fourth and fifth insulation layers 40 and 50. The fifth insulation layer 50 may be an organic layer.

The sixth insulation layer 60 may be disposed on the fifth insulation layer 50 to cover the second connection electrode CNE2. The sixth insulation layer 60 may be an organic layer. The stacked structure of the first to sixth insulation layers 10, 20, 30, 40, 50, and 60 is only an example, and in addition to the first to sixth insulation layers 10, 20, 30, 40, 50, and 60, a conductive layer and an insulation layer may be further disposed.

The light-emitting element layer 130 may be disposed on the circuit layer 120. The light-emitting element layer 130 may include a light-emitting element ED and a pixel-defining film PDL.

The light-emitting element ED may include an organic light-emitting element, an inorganic light-emitting element, an organic-inorganic light-emitting element, a quantum-dot light-emitting element, a micro-LED light-emitting element, or a nano-LED light-emitting element. However, an embodiment of the present disclosure is not limited thereto, and the light-emitting element ED may include various examples as long as being capable of generating light in response to electrical signals or controlling the amount of light.

The light-emitting element ED may include a first electrode AE (or anode), a light-emitting pattern EP, and a second electrode CE (or cathode). The first electrode AE may be disposed on the sixth insulation layer 60. The first electrode AE may be a translucent electrode, a semi-transmissive electrode, or a reflective electrode. The first electrode AE may include a reflective layer formed of Ag, Mg, Al, Pt, Pd, Au, Ni, Nd, Ir, Cr, or a compound thereof, and a translucent or semi-transmissive electrode layer formed on the reflective layer. The translucent or semi-transmissive electrode layer may include or may be formed of at least one selected from the group consisting of indium tin oxide (ITO), indium zinc oxide (IZO), indium gallium zinc oxide (IGZO), zinc oxide (ZnO), indium oxide (In203), and aluminum doped zinc oxide (AZO). For example, the first electrode AE may include or may be a stacked structure of ITO/Ag/ITO.

The pixel-defining film PDL may be disposed on the sixth insulation layer 60. According to an embodiment of the present disclosure, the pixel-defining film PDL may have light-absorbing characteristics. For example, the pixel-defining film PDL may have a black color. The pixel-defining film PDL may include a black coloring agent. The black coloring agent may include a black dye or a black pigment. The black coloring agent may include carbon black, metal such as chromium, or oxides thereof. The pixel-defining film PDL may correspond to a light-blocking pattern having light-blocking characteristics.

The pixel-defining film PDL may cover a portion of the first electrode AE. For example, an opening PDL-OP that exposes a portion of the first electrode AE may be defined in the pixel-defining film PDL. The opening PDL-OP of the pixel-defining film PDL may define a light-emitting region LA.

A hole control layer may be further disposed between the first electrode AE and the light-emitting pattern EP. The hole control layer may further include a hole transport layer and/or a hole injection layer. An electron control layer may be further disposed between the light-emitting pattern EP and the second electrode CE. The electron control layer may further include an electron transport layer and/or an electron injection layer.

The light-emitting element layer 130 may further include a capping layer. The capping layer may be disposed on the light-emitting element ED, and may cover the second electrode CE of the light-emitting element ED. The capping layer may include or may be formed of an organic material. The capping layer may be formed as a single layer or multiple layers. The capping layer may sufficiently protect the negative electrode and the organic light-emitting layer, disposed thereunder, from external water penetration or contamination, thereby making it possible to provide a light-emitting element ED with improved lifespan.

The thin-film encapsulation layer 140 may be disposed on the light-emitting element layer 130. The thin-film encapsulation layer 140 may protect the light-emitting element layer 130 from moisture, oxygen, and foreign substances such as dust particles. The thin-film encapsulation layer 140 may include a first inorganic layer 141, an organic layer 142, and a second inorganic layer 143 that are stacked in sequence, but the layers constituting the thin-film encapsulation layer 140 are not limited thereto.

The inorganic layers 141 and 143 may protect the light-emitting element layer 130 from moisture and oxygen, and the organic layer 142 may protect the light-emitting element layer 130 from foreign substances such as dust particles. The inorganic layers 141 and 143 may include or may be formed of a silicon nitride layer, a silicon oxynitride layer, a silicon oxide layer, a titanium oxide layer, or aluminum oxide layer. The organic layer 142 may include or may be formed of an acrylate-based organic layer, but an embodiment of the present disclosure is not limited thereto.

The input sensor layer ISL may be disposed on the display layer DPL. The input sensor layer ISL may be referred to as a sensor layer, an input-sensing layer, or an input-sensing panel. The input sensor layer ISL may include a base insulation layer 200-IL1, a first conductive layer 200-CL1, a sensing insulation layer 200-IL2, a second conductive layer 200-CL2, and a cover layer 200-IL3.

The base insulation layer 200-IL1 may be directly disposed on the display layer DPL. The base insulation layer 200-IL1 may be an inorganic layer including at least one of silicon nitride, silicon oxynitride, or silicon oxide. Alternatively, the base insulation layer 200-IL1 may also be an organic layer including an epoxy-based resin, an acrylate-based resin, or an imide-based resin. The base insulation layer 200-IL1 may have a single-layer structure, or a multi-layer structure in which multiple layers are stacked along a third direction DR3.

The first conductive layer 200-CL1 and the second conductive layer 200-CL2 may each have a structure of a single layer, or of multiple layers stacked along the third direction DR3. The first conductive layer 200-CL1 and the second conductive layer 200-CL2 may each include a mesh-structured sensing pattern or a bridge pattern.

The conductive layer having a single-layer structure may include a metal layer or a transparent conductive layer. The metal layer may include or may be formed of molybdenum, silver, titanium, copper, aluminum, or an alloy thereof. The transparent conductive layer may include or may be formed of a transparent conductive oxide such as indium tin oxide (ITO), indium zinc oxide (IZO), and indium zinc tin oxide (IZTO). The transparent conductive layer may include or may be formed of a conductive polymer such as PEDOT, metal nanowires, and graphene.

The conductive layer having a multi-layer structure may include metal layers. The metal layers may have, for example, a three-layer structure of titanium/aluminum/titanium. The conductive layer having a multi-layer structure may include or may be formed of at least one metal layer and at least one transparent conductive layer.

The sensing insulation layer 200-IL2 may be disposed between the first conductive layer 200-CL1 and the second conductive layer 200-CL2. The cover layer 200-IL3 may be disposed above the sensing insulation layer 200-IL2, and may cover the second conductive layer 200-CL2. The cover layer 200-IL3 may reduce or eliminate the probability of damage to the second conductive layer 200-CL2 in a later process. According to an embodiment of the present disclosure, the input sensor layer ISL may not include the cover layer 200-IL3.

Each of the sensing insulation layer 200-IL2 and the cover layer 200-IL3 may include or may be formed of an inorganic film. The inorganic film may include or may be formed of at least one of aluminum oxide, titanium oxide, silicon oxide, silicon nitride, silicon oxynitride, zirconium oxide, and hafnium oxide.

Alternatively, each of the sensing insulation layer 200-IL2 and the cover layer 200-IL3 may include or may be an organic film. The organic film may include or may be formed of at least one of an epoxy-based resin, a urethane-based resin, a cellulose-based resin, a siloxane-based resin, a polyimide-based resin, a polyamide-based resin, and a perylene-based resin.

FIG. 3 is a cross-sectional view of a display device DD according to an embodiment of the present disclosure. FIG. 3 will be described with reference to FIG. 2, and descriptions of the same reference numerals or symbols will be omitted. FIG. 3 illustrates a display device DD in which the window WM (see FIG. 2B) is omitted for the convenience of description. Description of each of first to third light-emitting elements ED1, ED2, and ED3 of FIG. 3 may be substantially same as the description of the light-emitting element ED of FIG. 2B.

Referring to FIG. 3, a display panel DP may include first to third light-emitting elements ED1, ED2, and ED3. The first light-emitting element ED1 may include a first anode AE1, a first light-emitting pattern EP1, and a portion of a cathode CE. The second light-emitting element ED2 may include a second anode AE2, a second light-emitting pattern EP2, and a portion of the cathode CE, and the third light-emitting element ED3 may include a third anode AE3, a third light-emitting pattern EP3, and a portion of the cathode CE. In some embodiments, the first to third light-emitting elements ED1, ED2, and ED3 may share the cathode CE.

The first to third anodes AE1, AE2, and AE3 may be provided in a plurality of patterns. In a pixel-defining film PDL, first to third light-emitting openings OP1-E, OP2-E, and OP3-E may be defined. The first light-emitting opening OP1-E may expose at least a portion of the first anode AE1. The second light-emitting opening OP2-E may expose at least a portion of the second anode AE2. The third light-emitting opening OP3-E may expose at least a portion of the third anode AE3.

The first to third light-emitting patterns EP1, EP2, and EP3 may be disposed on the first to third anodes AE1, AE2, and AE3, and the pixel-defining film PDL. The first to third light-emitting patterns EP1, EP2, and EP3 may be disposed respectively in the first to third light-emitting openings OP1-E, OP2-E, and OP3-E. The first light-emitting pattern EP1 may be disposed in the first light-emitting opening OP1-E, the second light-emitting pattern EP2 may be disposed in the second light-emitting opening OP2-E, and the third light-emitting pattern EP3 may be disposed in the third light-emitting opening OP3-E. The cathode CE may be disposed on the first to third light-emitting patterns EP1, EP2, and EP3 and the pixel-defining film PDL. In some embodiments, the cathode CE may be continuously formed on the first to third light-emitting patterns EP1, EP2, and EP3, and the pixel-defining film PDL.

FIGS. 2 and 3 exemplarily illustrate that the first to third light-emitting patterns EP1, EP2, and EP3 are disposed on the first to third anodes AE1, AE2, and AE3 and the pixel-defining film PDL, but an embodiment of the present disclosure is not limited thereto. For example, the first to third light-emitting patterns EP1, EP2, and EP3 may be disposed only on the first to third anodes AE1, AE2, and AE3.

The first to third light-emitting patterns EP1, EP2, and EP3 may provide light of different colors. For example, the first light-emitting pattern EP1 may provide red light, the second light-emitting pattern EP2 may provide green light, and the third light-emitting pattern EP3 may provide blue light.

An anti-reflection layer ARL may include a light-blocking pattern BM, a color filter CF, and an overcoat layer OC.

The light-blocking pattern BM may be disposed on an input sensor layer ISL. In an embodiment, the light-blocking pattern BM, which is a layer having a black color, may include a black coloring agent. The black coloring agent may include a black dye or black pigment. The black coloring agent may include carbon black, metal such as chromium, or oxides thereof. However, this is an example, and the material constituting the light-blocking pattern BM is not particularly limited as long as absorbing light.

The light-blocking pattern BM may prevent external light from being reflected by the first conductive layer 200-CL1 (see FIG. 2B) and the second conductive layer 200-CL2 (see FIG. 2B). The light-blocking pattern BM may overlap the pixel-defining film PDL. In the light-blocking pattern BM, first to third openings BM-OP1, BM-OP2, and BM-OP3 may be defined. The first to third openings BM-OP1, BM-OP2, and BM-OP3 of the light-blocking pattern BM may respectively overlap the first to third light-emitting openings OP1-E, OP2-E, and OP3-E of the pixel-defining film PDL. The first opening BM-OP1 may overlap the first light-emitting opening OP1-E, the second opening BM-OP2 may overlap the second light-emitting opening OP2-E, and the third opening BM-OP3 may overlap the third light-emitting opening OP3-E.

The first to third openings BM-OP1, BM-OP2, and BM-OP3 of the light-blocking pattern BM may respectively define first to third pixel regions PXA-R, PXA-G, and PXA-B. The first to third pixel regions PXA-R. PXA-G, and PXA-B may be defined as respective regions in which light generated from the first to third light-emitting elements ED1, ED2, and ED3 is emitted to the outside.

The color filter CF may include a first color filter CF1 and a second color filter CF2. In correspondence to the first to third light-emitting elements ED1, ED2, and ED3, the first color filter CF1 and the second color filter CF2 may transmit light generated from the first to third light-emitting elements ED1, ED2, and ED3, and block light in a certain wavelength band of external light. The first color filter CF1 may transmit a first color, the second color filter CF2 may transmit a second color and a third color. The second color may be different from the first color, and the third color may be different from the first and second colors. For example, the first color may be red, the second color may be green, and the third color may be blue. The first color filter CF1 and the second color filter CF2 may reduce external light reflection which is due to the first to third anodes AE1, AE2, and AE3 or the cathode CE.

The first color filter CF1 and the second color filter CF2 may overlap at least the first to third pixel regions PXA-R, PXA-G, and PXA-B. In particular, the first color filter CF1 may overlap the first light-emitting element ED1, and the second color filter CF2 may overlap the second light-emitting element ED2 and the third light-emitting element ED3. A portion of each of the first color filter CF1 and the second color filter CF2 may overlap a non-pixel region NPXA. For example, a portion of each of the first color filter CF1 and the second color filter CF2 may be disposed on the light-blocking pattern BM.

The second color filter CF2 may include a blue pigment. For example, the second color filter CF2 may include the following Compound B1 that is a blue pigment. However, this is only an example, and an embodiment of the present disclosure is not limited thereto.

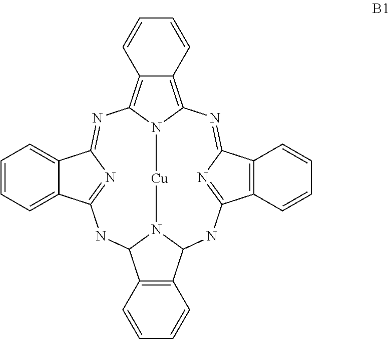

The second color filter CF2 may further include a green pigment. For example, the second color filter CF2 may include at least one of the following Compound G1, G2, and G3 that is a green pigment. However, this is only an example, and an embodiment of the present disclosure is not limited thereto.

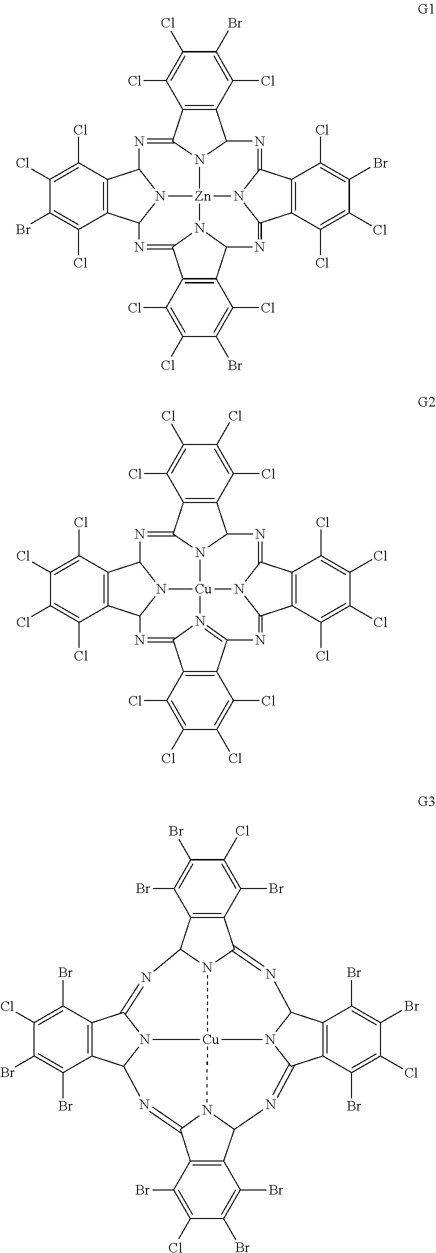

The second color filter CF2 may further include at least one of a blue-violet pigment and a yellow pigment. For example, the second color filter CF2 may include at least one of the following Compound V1, Y1, Y2, and Y3. However, this is only an example, and an embodiment of the present disclosure is not limited thereto.

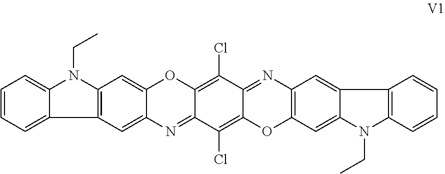 [SMILES: CCn1c2ccccc2c2cc3c(cc21)Oc1c(Cl)c2c(c(Cl)c1=N3)Oc1cc3c(cc1N=2)c1ccccc1n3CC]

The second color filter CF2 may include at least one of a blue pigment, a green pigment, a blue-violet pigment, and a yellow pigment. For example, the second color filter CF2 may include B1 that is a blue pigment, and at least one of G1, G2, G3, V1, Y1, Y2, and Y3. The

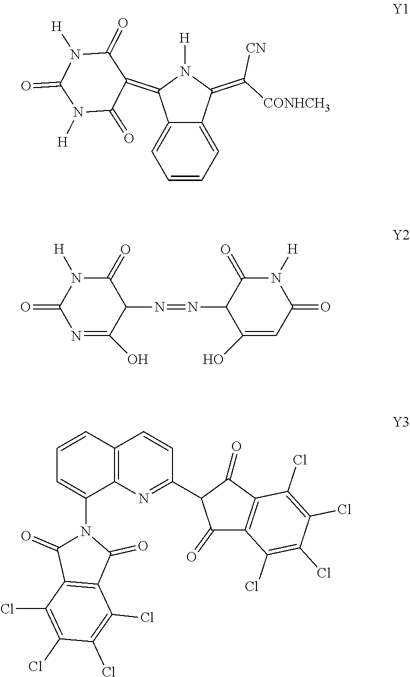

transmittance of the second color filter CF2 at each wavelength may be controlled by adjusting the thickness of the second color filter CF2, the composition ratio of pigments included in the second color filter CF2, or the concentrations of the pigments.

The second color filter CF2 may include a first sub-color filter SCF1 and a second sub-color filter SCF2. The first sub-color filter SCF1 and the second sub-color filter SCF2 may be spaced apart from each other. The first sub-color filter SCF1 may overlap the second light-emitting element ED2, and the second sub-color filter SCF2 may overlap the third light-emitting element ED3. The first sub-color filter SCF1 and the second sub-color filter SCF2 may include the same material, and may be formed through the same process. For example, the first sub-color filter SCF1 and the second sub-color filter SCF2 may be patterned using the same mask. Therefore, the number of masks required for forming the display device DD may be reduced, thereby improving the manufacturing process efficiency of a display device.

The overcoat layer OC may cover the light-blocking pattern BM, the first color filter CF1, and the second color filter CF2. The overcoat layer OC may include or may be formed of an organic material, and provide a flat upper surface.

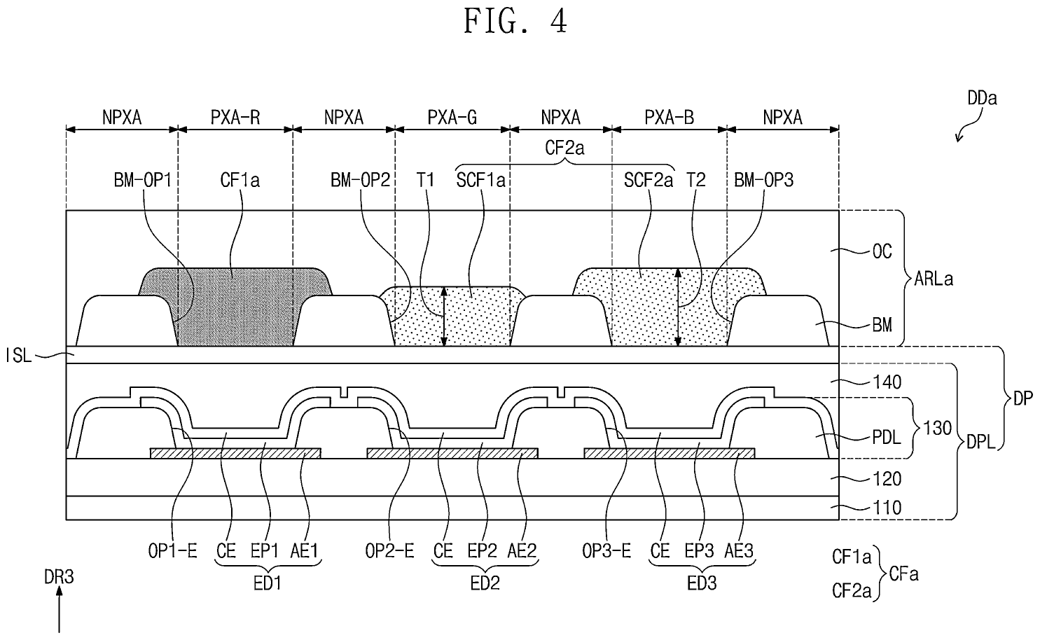

FIG. 4 is a cross-sectional view of a display device DDa according to an embodiment of the present disclosure. FIG. 4 illustrates a display device DDa in which the window WM (see FIG. 2B) is omitted for the convenience of description. FIG. 4 is described with reference to FIG. 3, and descriptions of the same reference numerals or symbols are omitted.

Referring to FIG. 4, the display device DDa may include a display layer DPL, an input sensor layer ISL, and an anti-reflection layer ARLa. The anti-reflection layer ARLa may include a light-blocking pattern BM, a color filter CFa, and an overcoat layer OC.

The color filter CFa may include a first color filter CF1a and a second color filter CF2a. The first color filter CF1a and the second color filter CF2a, corresponding to first to third light-emitting elements ED1, ED2, and ED3, may transmit light generated from the first to third light-emitting elements ED1, ED2, and ED3, and block light in a certain wavelength band of external light. The first color filter CF1a may transmit a first color, and the second color filter CF2a may transmit a second color and a third color. The second color may be different from the first color, and the third color may be different from the first and second colors. The first color may be red, the second color may be green, and the third color may be blue. The first color filter CF1a and the second color filter CF2a may reduce external light reflection which is due to first to third anodes AE1, AE2, and AE3, or a cathode CE.

The first color filter CF1a and the second color filter CF2a may overlap at least first to third pixel regions PXA-R, PXA-G, and PXA-B. In particular, the first color filter CF1a may overlap the first light-emitting element ED1, and the second color filter CF2a may overlap the second light-emitting element ED2 and the third light-emitting element ED3. A portion of each of the first color filter CF1a and the second color filter CF2a may also overlap a non-pixel region NPXA. For example, a portion of each of the first color filter CF1a and the second color filter CF2a may be disposed on a light-blocking pattern BM.

The second color filter CF2a may include a blue pigment. For example, the second color filter CF2a may include the following Compound B1 that is a blue pigment. However, this is only an example, and an embodiment of the present disclosure is not limited thereto.

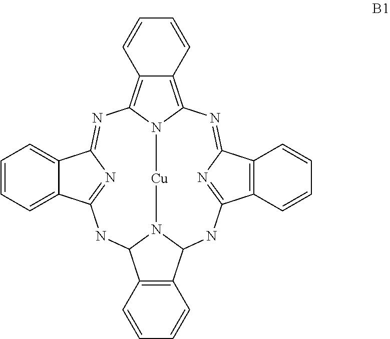

The second color filter CF2a may further include a green pigment. For example, the second color filter CF2a may include at least one of the following Compound G1, G2, and G3 that is a green pigment. However, this is only an example, and an embodiment of the present disclosure is not limited thereto.

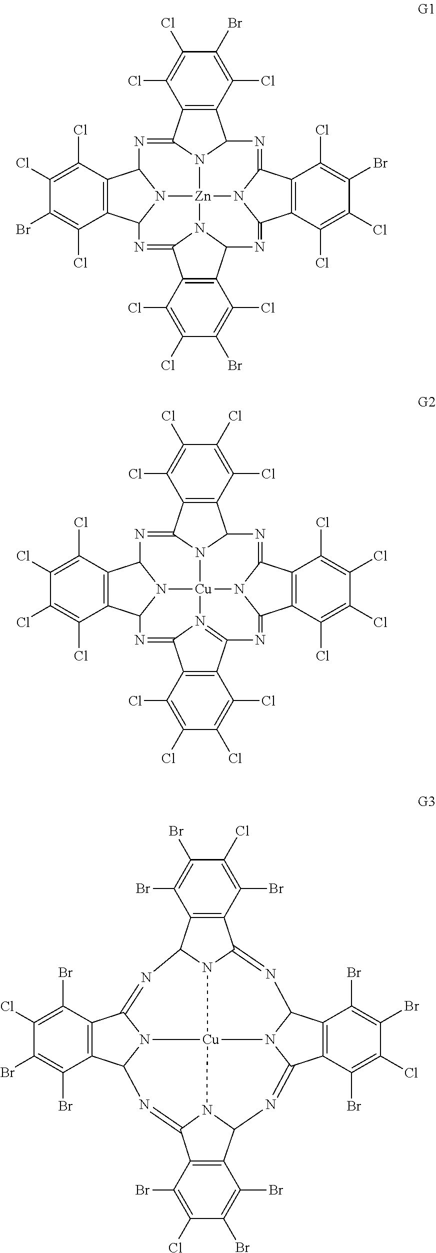

The second color filter CF2a may further include at least one of a blue-violet pigment and a yellow pigment. For example, the second color filter CF2a may include at least one of the following Compound V1, Y1, Y2, and Y3. However, this is only an example, and an embodiment of the present disclosure is not limited thereto.

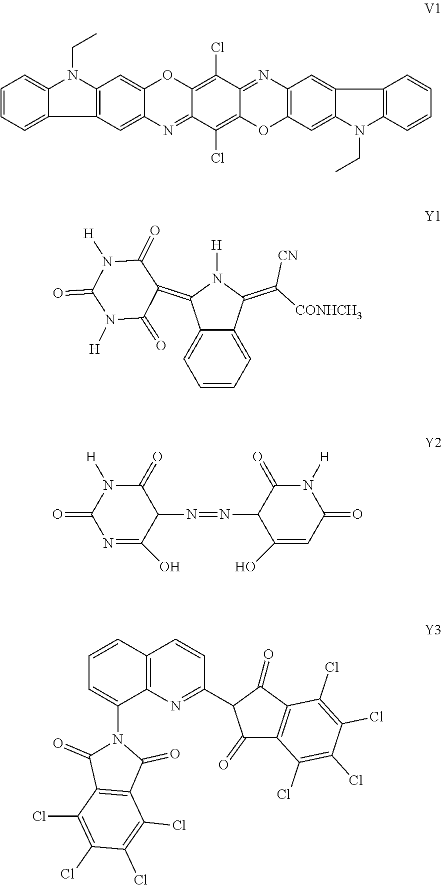

The second color filter CF2a may include at least one of a blue pigment, a green pigment, a blue-violet pigment, and a yellow pigment. For example, the second color filter CF2a may include B1 which is a blue pigment, and at least one of G1, G2, G3, V1, Y1, Y2, and Y3. The transmittance of the second color filter CF2a at each wavelength may be controlled by adjusting the thickness of the second color filter CF2a, the composition ratio of pigments included in the second color filter CF2a, or the concentrations of the pigments.

The second color filter CF2a may include a first sub-color filter SCF1a and a second sub-color filter SCF2a. The first sub-color filter SCF1a and the second sub-color filter SCF2a may be spaced apart from each other. The first sub-color filter SCF1a may overlap the second light-emitting element ED2, and the second sub-color filter SCF2a may overlap the third light-emitting element ED3. The first sub-color filter SCF1a and the second sub-color filter SCF2a may include the same material, and may be formed through the same process.

The first sub-color filter SCF1a may have a first thickness T1, and the second sub-color filter SCF2a may have a second thickness T2. The first thickness T1 and the second thickness T2 may differ from each other. The first sub-color filter SCF1a and the second sub-color filter SCF2a may be patterned using the same mask, but the first sub-color filter SCF1a and the second sub-color filter SCF2a, which have different thicknesses, may be patterned using a half-tone mask or slit.

In particular, the second color filter CF2a may be exposed in a state in which a mask is aligned. One portion of the second color filter CF2a exposed to light, during an exposure process, may be hardened, and another portion of the second color filter CF2a not exposed to light may be removed. The hardened portion of the second color filter CF2a may serve as the first sub-color filter SCF1a and the second sub-color filter SCF2a, and the removed portion of the second color filter CF2a may overlap the light-blocking pattern BM. In the above-mentioned exposure process, the first sub-color filter SCF1a and the second sub-color filter SCF2a having different thicknesses may be patterned using a half-tone mask or slit. The half-tone mask or slit has the characteristic of blocking only part of light. Therefore, at least a portion of a part of the second color filter CF2a, overlapping a region where only part of light is blocked, may be removed, and thus the part of the second color filter CF2a, overlapping a region where only part of light is blocked, may have a smaller thickness than a part of the second color filter CF2a overlapping a region where light is entirely transmitted.

The second thickness T2 may be larger than the first thickness T1. The part of the second color filter CF2a overlapping a region where only part of light is blocked may serve as the first sub-color filter SCF1a. Since the second thickness T2 of the second sub-color filter SCF2a is larger than the first thickness T1 of the first sub-color filter SCF1a, the transmittance, for the second color, of the second light-emitting region PXA-G overlapping the first sub-color filter SCF1a may be improved, and the reflectance of the third light-emitting region PXA-B overlapping the second sub-color filter SCF2a may be reduced. For example, since the second thickness T2 of the second sub-color filter SCF2a is larger than the first thickness T1 of the first sub-color filter SCF1a, the transmittance of the second light-emitting region PXA-G for light in the wavelength band around 530 nm, corresponding to a green color, may be improved, and the reflectance of the third light-emitting region PXA-B transmitting a blue color may be reduced. That is, by adjusting the thicknesses of the first sub-color filter SCF1a and the second sub-color filter SCF2a, the reflectance of the third light-emitting region PXA-B may become lower than in case of the first sub-color filter SCF1 and the second sub-color filter SCF2 of FIG. 3 having the same thickness. Therefore, the quality of the display device DDa may be improved.

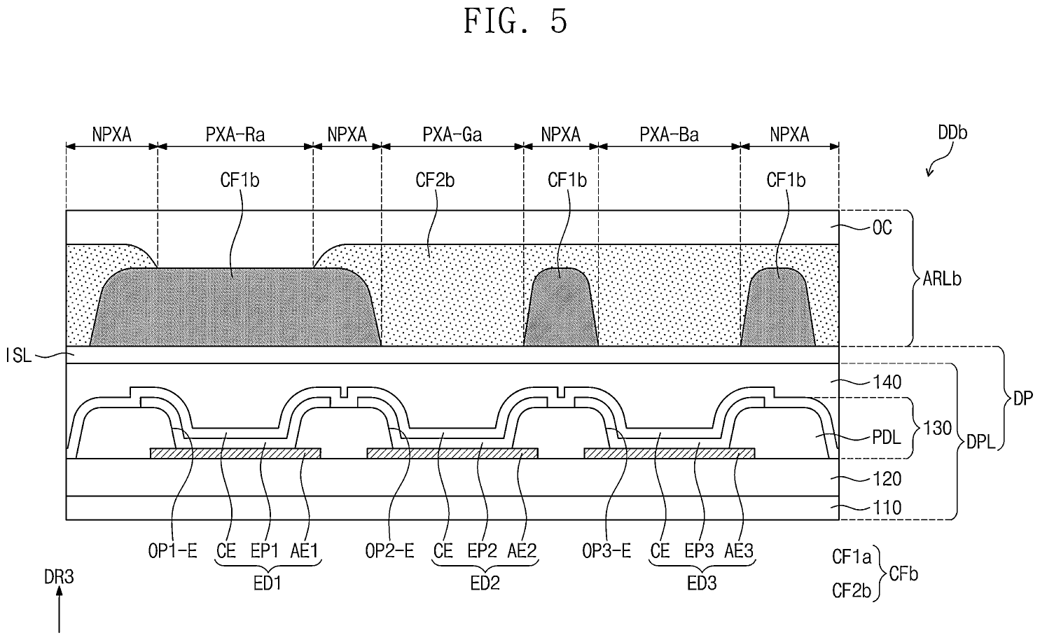

FIG. 5 is a cross-sectional view of a display device DDb according to an embodiment of the present disclosure. FIG. 5 illustrates the display device DDb in which the window WM (see FIG. 2B) is omitted for the convenience of description. FIG. 5 is described with reference to FIG. 3, and descriptions of the same reference numerals or symbols are omitted.

Referring to FIG. 5, the display device DDb may include a display layer DPL, an input sensor layer ISL, and an anti-reflection layer ARLb. The anti-reflection layer ARLb may include a color filter CFb and an overcoat layer OC.

The color filter CFb may include a first color filter CF1b and a second color filter CF2b. The first color filter CF1b and the second color filter CF2b, corresponding to first to third light-emitting elements ED1, ED2, and ED3, may transmit light generated from the first to third light-emitting elements ED1, ED2, and ED3, and block light in a certain wavelength band of external light. For example, the first color filter CF1b may disposed over the first light-emitting element ED1, and the second color filter CF2b may disposed over the second and third light-emitting elements ED2 and ED3. The first color filter CF1b may transmit a first color, and the second color filter CF2b may transmit a second color and a third color. The second color may be different from the first color, and the third color may be different from the first color and the second color. The first color may be red, the second color may be green, and the third color may be blue. The first color filter CF1b and the second color filter CF2b may reduce the external light reflection by the first to third anodes AE1, AE2, and AE3, or the cathode CE.

The second color filter CF2b may include a blue pigment. For example, the second color filter CF2b may include the following Compound B1 that is a blue pigment. However, this is only an example, and an embodiment of the present disclosure is not limited thereto.

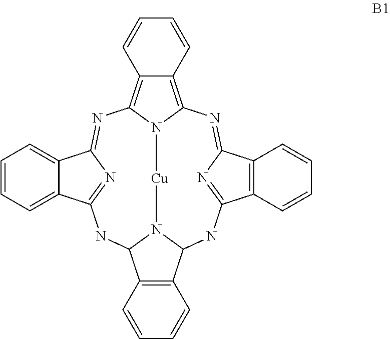

The second color filter CF2b may further include a green pigment. For example, the second color filter CF2b may include at least one of the following Compound G1, G2, and G3 that is a green pigment. However, this is only an example, and an embodiment of the present disclosure is not limited thereto.

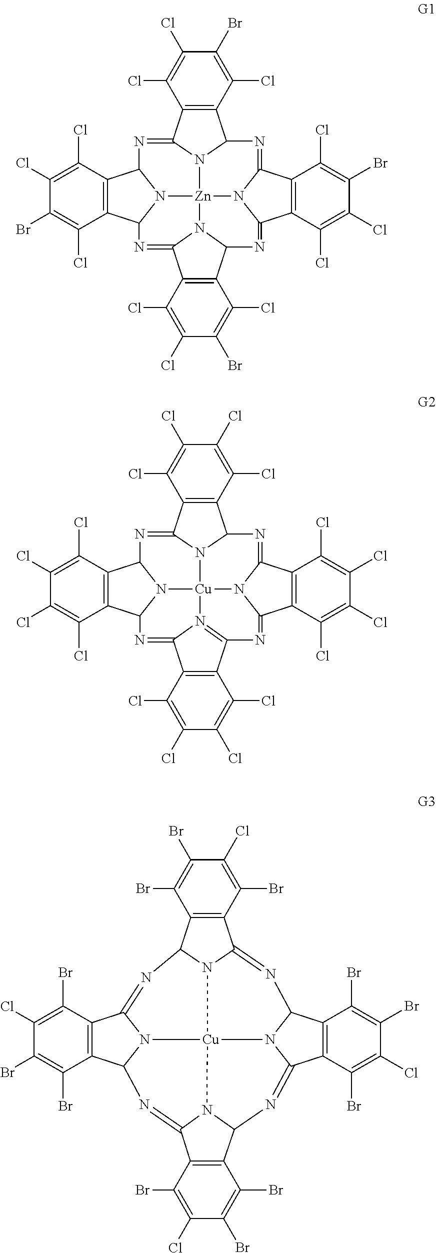

The second color filter CF2b may further include at least one of a blue-violet pigment and a yellow pigment. For example, the second color filter CF2b may include at least one of the following Compound V1, Y1, Y2, and Y3. However, this is only an example, and an embodiment of the present disclosure is not limited thereto.

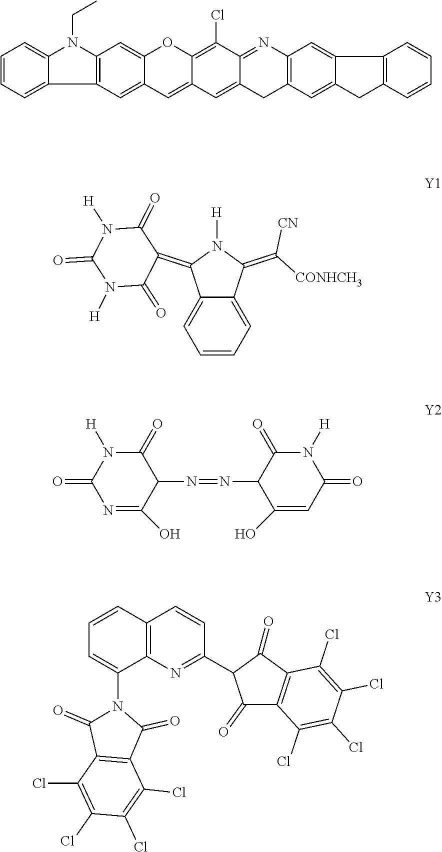

The second color filter CF2b may include at least one of a blue pigment, a green pigment, a blue-violet pigment, and a yellow pigment. For example, the second color filter CF2b may include B1 that is a blue pigment, and include at least one of G1, G2, G3, V1, Y1, Y2, and Y3. The transmittance of the second color filter CF2b at each wavelength may be controlled by adjusting the thickness of the second color filter CF2b, the composition ratio of pigments included in the second color filter CF2b, or the concentrations of the pigments.

A region overlapping one color filter CF1b or CF2b may be defined as a pixel region PXA-Ra, PXA-Ga, or PXA-Ba, and a region overlapping a plurality of color filters CF1b and CF2b may be defined as a non-pixel region NPXA. For example, a region overlapping the first color filter CF1b may be defined as a first pixel region PXA-Ra, regions overlapping the second color filter CF2b may be defined as a second pixel region PXA-Ga and a third pixel region PXA-Ba, respectively. A region overlapping the first color filter CF1b and the second color filter CF2b may be defined as the non-pixel region NPXA. In some embodiments, the non-pixel region NPXA may be defined as a region where the first color filter CF1b and the second color filter CF2b overlap each other, which serves as the light-blocking pattern BM of FIG. 3, for example. The first pixel region PXA-Ra may correspond to a region where a portion of the first color filter CF1b, which does not overlap the second color filter CF2b, is disposed. The second and third pixel regions PXA-Ga and PXA-Ba may correspond to a region where a portion of the second color filter CF2b, which does not overlap the first color filter CF1b, is disposed.

The first color filter CF1b may overlap the first light-emitting element ED1 and a pixel-defining film PDL, and the second color filter CF2b may overlap the second light-emitting element ED2, the third light-emitting element ED3, and the pixel-defining film PDL. That is, a portion of the first color filter CF1b may overlap a portion of the second color filter CF2b in a region where the pixel-defining film PDL is disposed. The region where the first color filter CF1b and the second color filter CF2b overlap each other may not transmit light. As the first color filter CF1b and the second color filter CF2b overlap each other, and the overlapped region serves as the light-blocking pattern BM (see FIG. 3), a process of forming the light-blocking pattern BM may be omitted. Since the number of masks required for forming the display device DDb is reduced, the manufacturing process efficiency of a display device may be improved.

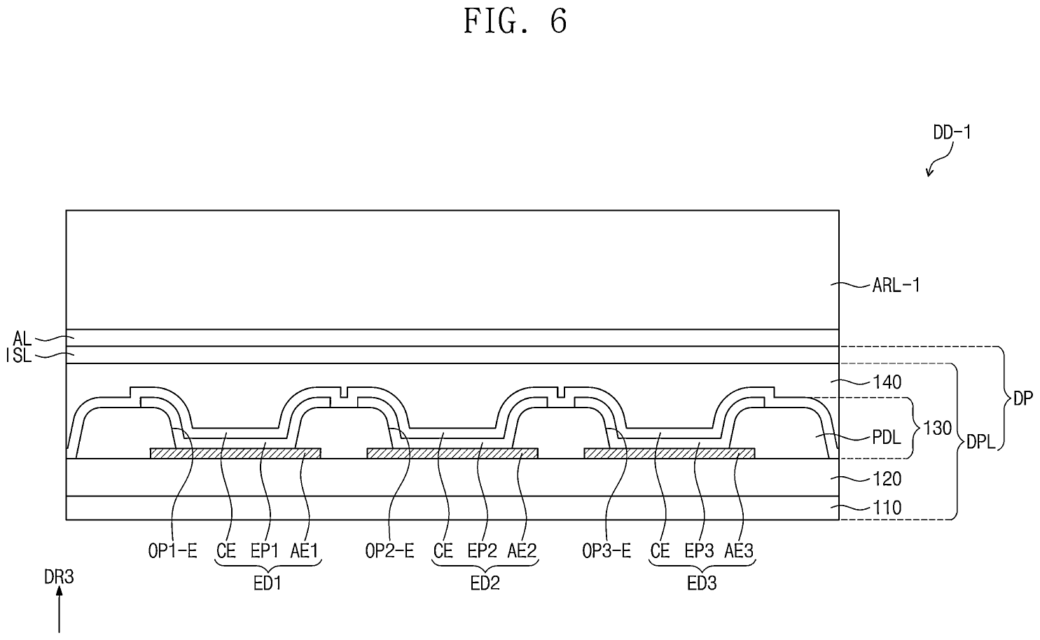

FIG. 6 is a cross-sectional view of a display device DD-1 according to a comparative example of the present disclosure. FIG. 6 illustrates the display device DD-1 in which the window WM (see FIG. 2B) is omitted for the convenience of description. FIG. 6 is described with reference to FIG. 3, and descriptions of the same reference numerals or symbols are omitted.

Referring to FIG. 6, the display device DD-1 may include a display layer DPL, an input sensor layer ISL, an anti-reflection layer ARL-1. The anti-reflection layer ARL-1 may be disposed on the input sensor layer ISL. The anti-reflection layer ARL-1 may be an optical member, and may lower the reflectance of light incident from the outside. The anti-reflection layer ARL-1 may include a phase retarder and/or polarizer. The anti-reflection layer ARL-1 may include at least a polarizing film. The anti-reflection layer ARL-1 may be bonded to a display panel DP by an adhesive layer AL. The adhesive layer AL may be an optically clear adhesive (OCA) or a pressure sensitive adhesive film (PSA), but is not limited particularly thereto.

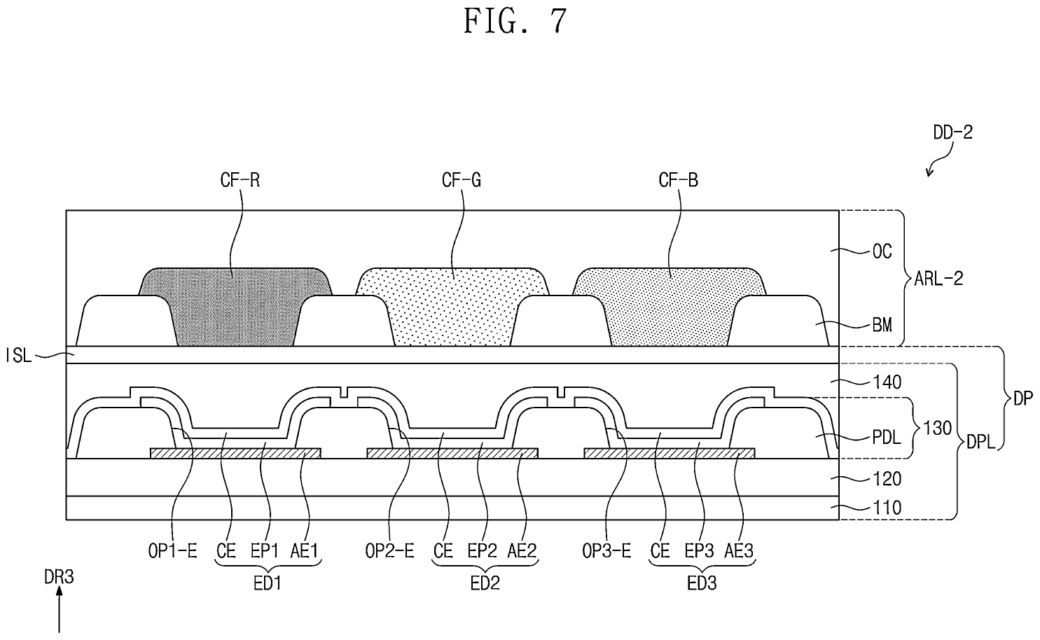

FIG. 7 is a cross-sectional view of a display device DD-2 according to a comparative example of the present disclosure. FIG. 7 illustrates the display device DD-2 in which the WM (see FIG. 2B) is omitted for the convenience of description. FIG. 7 is described with reference to FIG. 3, and descriptions of the same reference numerals or symbols are omitted.

Referring to FIG. 7, the display device DD-2 may include a display layer DPL, an input sensor layer ISL, and an anti-reflection layer ARL-2. The anti-reflection layer ARL-2 may include a light-blocking pattern BM, a plurality of color filters CF-R, CF-G, and CF-B, and an overcoat layer OC.

The plurality of color filters CF-R, CF-G, and CF-B may include a red color filter CF-R, a green color filter CF-G, and a blue color filter CF-B. The red color filter CF-R, the green color filter CF-G, and the blue color filter CF-B may be disposed on the input sensor layer ISL and the light-blocking pattern BM. The red color filter CF-R may overlap a first light-emitting element ED1, and transmit a first color generated from the first light-emitting element ED1. The green color filter CF-G may overlap a second light-emitting element ED2, and transmit a second color generated from the second light-emitting element ED2. The blue color filter CF-B may overlap a third light-emitting element ED3, and transmit a third color generated from the third light-emitting element ED3. The second color may be different from the first color, and the third color may be different from the first color and the second color.

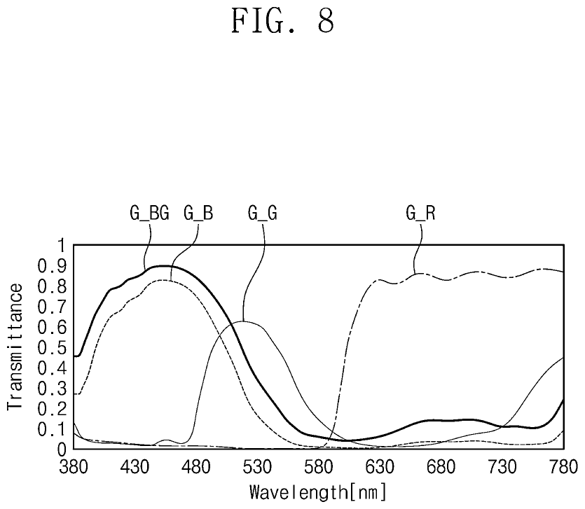

FIG. 8 is a diagram showing a transmittance graph G_BG of the second color filter CF2 in FIG. 3 versus a wavelength, and respective transmittance graphs G_R, G_G, and G_B of the red color filter CF-R, the green color filter CF-G, and the blue color filter CF-B in FIG. 7 versus a wavelength.

Referring to FIGS. 3, 7 and 8, the horizontal axis represents the wavelength (nm), and the vertical axis represents the transmittance. For the convenience of description, the transmittance graphs G_R, G_G, G_B, and G_BG versus a wavelength are referred to as first to fourth graphs G_R, G_G, G_B, and G_BG, respectively.

The first graph G_R shows the transmittance of the red color filter CF-R in FIG. 7, the second graph G_G shows the transmittance of the green color filter CF-G in FIG. 7, and the third graph G_B shows the transmittance of the blue color filter CF-B in FIG. 7. The display device DD-2 in FIG. 7 corresponds to a comparative example of the present disclosure. The fourth graph G_BG shows the transmittance of the second color filter CF2 in FIG. 3. The display device DD in FIG. 3 corresponds to an embodiment of the present disclosure.

The second color filter CF2 may be obtained by adjusting the thickness of the blue color filter CF-B, the concentrations of the pigments, or combinations of the pigments. The transmittance in the fourth graph G_BG may be more improved than in the third graph G_B. In particular, the transmittance of light in a wavelength around 530 nm, corresponding to a green color, may be improved. Accordingly, the second color filter CF2 may transmit both the blue and green colors. As a result, a single second color filter CF2 may be patterned in the second light-emitting region PXA-G (see FIG. 3) and the third light-emitting region PXA-B (see FIG. 3) using the same mask, and thus the number of masks required for forming the display device DD may be reduced, thereby improving the manufacturing process efficiency of a display device. Moreover, the display device DD including the second color filter CF2 may have more improved luminous efficiency than the display device DD-1 including a polarizing film.

According to what is described above, a display device may include a first sub-color filter overlapping a second light-emitting element, and a second sub-color filter overlapping a third light-emitting element. The first sub-color filter and the second sub-color filter may be patterned using the same mask. Therefore, the number of masks required for forming the display device may be reduced, and the manufacturing process efficiency of a display device may be improved.

Moreover, the thickness of the color filter, the concentrations of pigments, or the combination of the pigments may be adjusted to control the transmittance of the color filter at each wavelength. Since a second thickness of the second sub-color filter may be larger than a first thickness of the first sub-color filter, the transmittance of a second color in a second light-emitting region, overlapping the first sub-color filter, may be improved, and the reflectance of a third light-emitting region overlapping the second sub-color filter may be reduced. Therefore, the quality of the display device may be improved.

According to what is described above, a portion of the first color filter may overlap a portion of the second color filter in a region where a pixel-defining film is disposed. As the first color filter and the second color filter overlap each other, and the overlapped region serves as a light-blocking pattern, a process of forming a light-blocking pattern may be omitted. Since the number of masks required for forming a display device is reduced, the manufacturing process efficiency of a display device may be improved.

Although the embodiments of the present disclosure have been described, it is understood that the present disclosure should not be limited to these embodiments but various changes and modifications can be made by one ordinary skilled in the art within the spirit and scope of the present disclosure as hereinafter claimed. Therefore, the technical scope of the present disclosure should not be limited to the contents described in the detailed description of the specification, but should be defined by the claims.

What is claimed is:

1. A display device comprising:
a display panel including a pixel-defining film in which a first light-emitting opening, a second light-emitting opening, and a third light-emitting opening are defined, and a first light-emitting element, a second light-emitting element, and a third light-emitting element which are disposed respectively in the first to third light-emitting openings, and configured to provide light of different colors; and
an anti-reflection layer disposed on the display panel, and including a first color filter and a second color filter,
wherein the first color filter overlaps the first light-emitting element, and the second color filter overlaps the second light-emitting element and the third light-emitting element.

2. The display device of claim 1,
wherein the first color filter transmits a first color, and the second color filter transmits a second color and a third color which are different from the first color.

3. The display device of claim 1,
wherein the second color filter comprises a blue pigment.

4. The display device of claim 3,
wherein the second color filter further comprises a green pigment.

5. The display device of claim 3,
wherein the second color filter further comprises at least one of a blue-violet pigment and a yellow pigment.

6. The display device of claim 1,
wherein the anti-reflection layer further comprises an overcoat layer covering the first color filter and the second color filter.

7. The display device of claim 1,
wherein the second color filter comprises a first sub-color filter overlapping the second light-emitting element, and a second sub-color filter overlapping the third light-emitting element.

8. The display device of claim 7,
wherein the first sub-color filter and the second sub-color filter are spaced apart from each other.

9. The display device of claim 7,
wherein the first sub-color filter and the second sub-color filter comprise a same material.

10. The display device of claim 7,
wherein the anti-reflection layer further comprises a light-blocking pattern overlapping the pixel-defining film.

11. The display device of claim 7,
wherein the first sub-color filter has a first thickness, and the second sub-color filter has a second thickness greater than the first thickness.

12. The display device of claim 1,
wherein the first color filter overlaps the first light-emitting element and the pixel-defining film, and the second color filter overlaps the second light-emitting element, the third light-emitting element, and the pixel-defining film.

13. The display device of claim 1,
wherein a portion of the first color filter overlaps a portion of the second color filter in a region where the pixel-defining film is disposed.

14. A display device comprising:
a display panel including a pixel-defining film in which a first light-emitting opening, a second light-emitting opening, and a third light-emitting opening are defined, and a first light-emitting element, a second light-emitting element, and a third light-emitting element which are disposed respectively in the first to third light-emitting openings, and configured to provide light of different colors; and
an anti-reflection layer disposed on the display panel,
wherein the anti-reflection layer includes:
a first color filter configured to transmit a first color, and
a second color filter including a blue pigment and configured to transmit a second color different from the first color, and a third color different from the first color and the second color.

15. The display device of claim 14,
wherein the first color filter overlaps the first light-emitting element, and the second color filter overlaps the second light-emitting element and the third light-emitting element.

16. The display device of claim 14,
wherein the second color filter comprises a first sub-color filter overlapping the second light-emitting element, and a second sub-color filter overlapping the third light-emitting element, and
wherein the first sub-color filter and the second sub-color filter include a same material.

17. The display device of claim 16,
wherein the anti-reflection layer further comprises a light-blocking pattern overlapping the pixel-defining film, and
wherein the first sub-color filter and the second sub-color filter are spaced apart from each other.

18. The display device of claim 16,
wherein the first sub-color filter has a first thickness, and the second sub-color filter has a second thickness greater than the first thickness.

19. The display device of claim 14,
wherein the first color filter overlaps the first light-emitting element and the pixel-defining film, and
wherein the second color filter overlaps the second light-emitting element, the third light-emitting element, and the pixel-defining film.

20. The display device of claim 14,
wherein a portion of the first color filter overlaps a portion of the second color filter in a region where the pixel-defining film is disposed.
